(19) United States
(12) Patent Application Publication
(10) Pub. No.: US 2026/0059975 A1
(43) Pub. Date: Feb. 26, 2026

(54) DISPLAY APPARATUS

(71) Applicant: LG Display Co., Ltd., Seoul (KR)

(72) Inventor: Juhan KIM, Paju-si (KR)

(73) Assignee: LG Display Co., Ltd., Seoul (KR)

(21) Appl. No.: 19/090,727

(22) Filed: Mar. 26, 2025

(30) Foreign Application Priority Data
Aug. 21, 2024 (KR) 10-2024-0111727

(51) Int. Cl. H10K 59/80; H10K 59/95

(52) U.S. Cl. CPC H10K 59/873; H10K 59/8792; H10K 59/8794; H10K 59/95

(57) ABSTRACT

A display apparatus can include a display panel, a cover layer disposed on the display panel and extending beyond the display panel, a sensor disposed outside the display panel and overlapping the cover layer, and a blocking member between the display panel and the sensor in a plan view. The display apparatus can further include a back plate below the display panel and a heat dissipation sheet below the back plate.

### CROSS-REFERENCE TO RELATED APPLICATION

The present application claims priority to Korean Patent Application No. 10-2024-0111727, filed Aug. 21, 2024 in the Republic of Korea, the entire contents of which is hereby expressly incorporated by reference into the present application.

### BACKGROUND

### Technical Field

The present disclosure relates to a display apparatus.

### Discussion of the Related Art

As the information society develops, various demands for display apparatuses for displaying images are increasing. Various types of display apparatuses, such as a liquid crystal display (LCD) apparatus and an organic light-emitting diode (OLED) display apparatus, are being utilized.

Among the display apparatuses, there is an advantage in that the OLED display apparatus as the self-luminous type has a wider viewing angle and a high contrast ratio, and can be lighter and thinner and has less power consumption than the LCD apparatus because it does not require a separate backlight. In addition, there is an advantage in that the OLED display apparatus can drive at a low voltage, have a fast response time, and especially have the inexpensive manufacturing cost.

The OLED display apparatus can also be applied to display apparatuses mounted on vehicles. A display apparatus mounted on a vehicle can further include a sensor for sensing external light.

When the display apparatus mounted on the vehicle includes the sensor, light or heat emitted from the sensor can damage an OLED display apparatus, and thus light or heat needs to be blocked.

### SUMMARY OF THE DISCLOSURE

The present disclosure is directed to providing a display apparatus having a design with improved aesthetic feeling.

The present disclosure is also directed to providing a display apparatus capable of serving to both display a screen and sense external light.

The present disclosure is also directed to providing a display apparatus capable of suppressing or preventing damage due to heat and/or light emitted by a sensor for sensing external light.

The present disclosure is also directed to providing a display apparatus with improved reliability by reducing the risk of the life reduction and degradation.

Objects of the present disclosure are not limited to the above-described objects, and other technical objects can be inferred from the following embodiments.

According to one or more embodiments of the present disclosure, there is provided a display apparatus including a display panel, a cover layer disposed on the display panel and extending more than the display panel, a sensor disposed outside the display panel and overlapping the cover layer, and a blocking member between the display panel and the sensor in a plan view.

According to another embodiment of the present disclosure, there is provided a display apparatus including a display panel, a sensor disposed outside the display panel and disposed below the display panel, and a blocking member in contact with a side surface of the display panel and including a white-based resin or foam tape, wherein the blocking member is disposed between the display panel and the sensor in a plan view.

Detailed matters of other embodiments are included in the detailed description and accompanying drawings.

According to the embodiments of the present disclosure, it is possible to provide the display apparatus with improved aesthetic feeling.

According to the embodiments of the present disclosure, it is possible to provide the display apparatus capable of serving to both display the screen on the light-emitting part and sense external light.

According to the embodiments of the present disclosure, it is possible to suppress or prevent damage due to heat and/or light emitted by the sensor for sensing external light.

According to the embodiments of the present disclosure, it is possible to improve reliability by reducing the risk of the life reduction and degradation.

According to the embodiments of the present disclosure, it is possible to suppress or prevent damage due to the sensor, thereby increasing the life of the display apparatus and reducing power consumption and/or production energy.

However, effects obtainable from the present disclosure are not limited to the above-described effects, and other effects that are not mentioned will be able to be clearly understood by those skilled in the art to which the present disclosure pertains from the following description.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display apparatus according to one or more embodiments of the present disclosure.

FIG. 2 is a cross-sectional view along line A-A′ in FIG. 1.

FIG. 3 is a plan view of a display panel according to one embodiment of the present disclosure.

FIG. 4 is an enlarged view of area Q1 in FIG. 3.

FIG. 5 is a view illustrating only a display panel of FIG. 4.

FIG. 6 is a cross-sectional view of a pixel of the display panel according to one embodiment of the present disclosure.

FIG. 7 is a schematic cross-sectional view of a display apparatus according to one embodiment of the present disclosure.

FIG. 8 is a cross-sectional view of a display apparatus according to another embodiment of the present disclosure.

FIG. 9 is a plan view of a display apparatus according to still another embodiment of the present disclosure.

FIG. 10 is an enlarged view of area Q2 in FIG. 9.

FIG. 11 is a cross-sectional view along line B-B′ in FIG. 10.

FIG. 12 is a plan view of a display panel according to still another embodiment of the present disclosure.

FIG. 13 is a plan view of a display apparatus according to yet another embodiment of the present disclosure.

FIG. 14 is a plan view of a display panel according to yet another embodiment of the present disclosure.

FIG. 15 is an enlarged view of area Q3 in FIG. 14.

### DETAILED DESCRIPTION OF THE EMBODIMENTS

Hereinafter, various embodiments of the present disclosure will be described with reference to the accompanying drawings. In the specification, when a first component (or an area, a layer, a portion, etc.) is described as “on,” “connected,” or “coupled to” a second component, it means that the first component can be directly connected/coupled to the second component or a third component can be disposed therebetween.

The same reference numerals indicate the same components. In addition, in the drawings, thicknesses, proportions, and dimensions of components are exaggerated for effective description of technical contents. The term “and/or” includes all one or more combinations that can be defined by the associated configurations.

Terms such as “first” and “second” can be used to describe various components, but the components are not limited by the terms. The terms are used only for the purpose of distinguishing one component from another and may not define order or sequence. For example, a first component can be referred to as a second component, and similarly, the second component can also be referred to as the first component without departing from the scopes of the embodiments of the present disclosure. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the disclosure and does not preclude the presence or addition possibility of one or more other features, numbers, steps, operations, components, parts, or combinations thereof in advance. Further, the term “can” encompasses all the meanings and coverages of the term “may”and vice versa.

Now, example embodiments of the present disclosure will be discussed. All the components of each display apparatus according to all embodiments of the present disclosure are operatively coupled and configured.

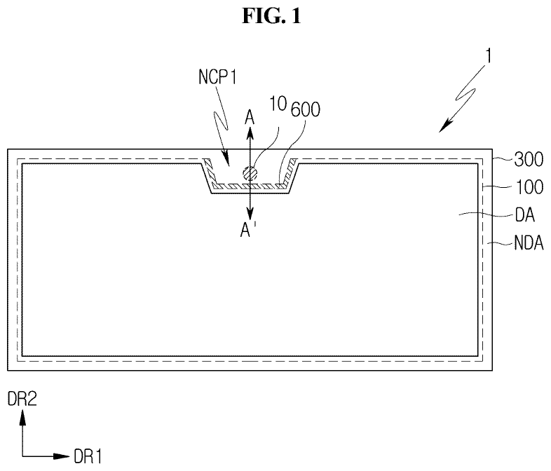

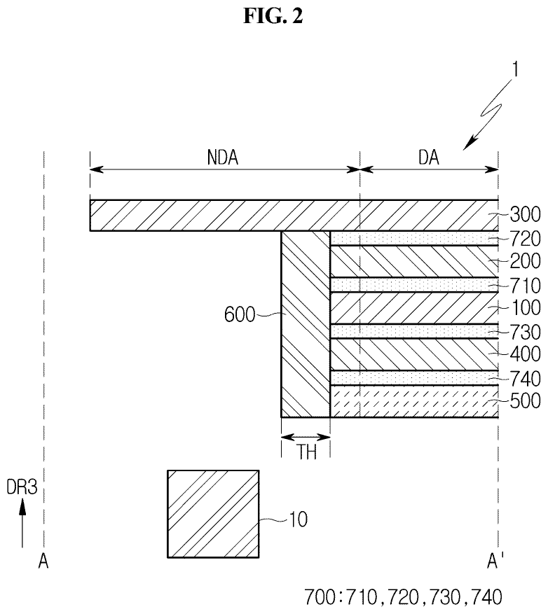

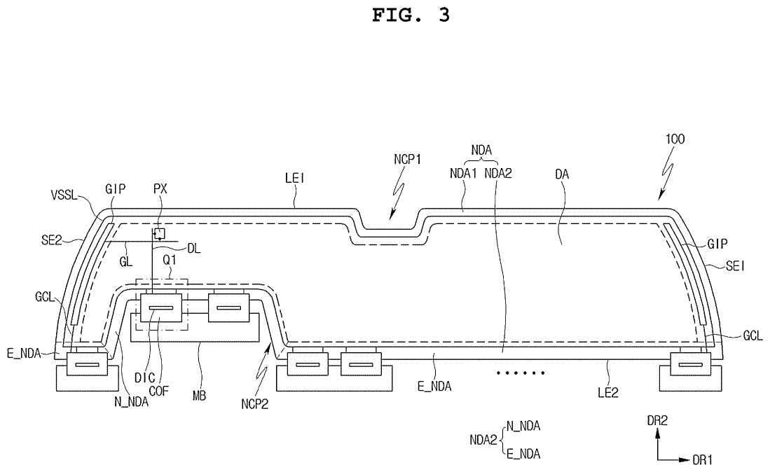

FIG. 1 is a schematic plan view of a display apparatus according to one or more embodiments of the present disclosure. FIG. 2 is a cross-sectional view along line A-A′ in FIG. 1. FIG. 3 is a plan view of a display panel according to one embodiment of the present disclosure.

In FIG. 3, a display panel 100 is illustrated as having a different flat surface shape from a flat surface shape of a display apparatus 1 of FIG. 1. The flat surface shape of the display apparatus 1 of FIG. 1 can correspond to the flat surface shape of the display panel 100, but, for convenience of description, a plan view of the display apparatus 1 of FIG. 1 is schematically illustrated.

Referring to FIGS. 1 to 3, the display apparatus 1 can be an apparatus including both a display function for displaying a video and a touch sensing function for sensing touch of a user, but is not limited thereto. For example, the display apparatus 1 can include only one of the display function for displaying a video and the touch sensing function for sensing touch of a user.

The display apparatus 1 can be an electroluminescent display apparatus or a micro light-emitting diode display apparatus that includes a touch sensor. The electroluminescent display apparatus including the touch sensor can be an organic light-emitting diode (OLED) display apparatus, a quantum-dot light-emitting diode display apparatus, or an inorganic light-emitting diode display apparatus.

The display apparatus 1 according to the present embodiment can be a vehicle display apparatus, but is not limited thereto. For example, the description of the display apparatus 1 can be applied without limitation to the type of the apparatus as long as a display apparatus is an apparatus including a display function.

When the display apparatus 1 according to the present embodiment is a vehicle display apparatus, the display apparatus 1 can include a function of manipulating at least some of various functions of a vehicle, a function of displaying various pieces of information about the vehicle, etc.

When the display apparatus 1 according to the present embodiment is a vehicle display apparatus, the display apparatus 1 can be disposed on a dashboard of a vehicle. The display apparatus 1 can be disposed across a driver's seat and a passenger's seat that are disposed at front seats of a vehicle, but is not limited thereto. Both a driver in the driver's seat and a co-driver in the passenger's seat can use the display apparatus 1.

However, a location at which the display apparatus 1 is disposed is not limited thereto. For example, the display apparatus 1 can be applied to various locations, such as a room mirror inside a vehicle, a side mirror outside the vehicle, rear surfaces of a driver's seat and a passenger's seat in order to display a screen to a co-driver in a back seat.

The display apparatus 1 can include a display area DA and a non-display area NDA.

The display area DA can be an area in which light is emitted to the outside to display a screen. The display area DA can further include a function of sensing touch of a user. In this case, the display area DA can correspond to a touch sensing area, but is not limited thereto.

The non-display area NDA can be an area in which light is not emitted to the outside so as not to display a screen. The non-display area NDA can be located around the display area DA. The non-display area NDA can surround the display area DA, but the embodiments of the present disclosure are not limited thereto. The non-display area NDA can surround the display area DA entirely or only in part(s). A bezel area of the display apparatus 1 can be defined by the non-display area NDA, but the embodiments of the present disclosure are not limited thereto.

The display area DA of the display apparatus 1 can be substantially the same as the display area DA of the display panel 100.

The non-display area NDA of the display apparatus 1 can include the non-display area NDA of the display panel 100 and can be further disposed to extend outward from the non-display area NDA of the display panel 100. The non-display area NDA of the display apparatus 1 can extend from the non-display area NDA of the display panel 100 to correspond to an area in which a cover layer 300 is disposed.

The display apparatus 1 can include the display panel 100, a polarization layer 200 disposed on the display panel 100, the cover layer 300 disposed above the polarization layer 200, a back plate 400 disposed below the display panel 100, and a heat dissipation sheet 500 disposed below the back plate 400.

The display apparatus 1 can include an adhesive layer 700 (710, 720, 730, and 740) disposed between the display panel 100, the polarization layer 200, the cover layer 300, the back plate 400, and the heat dissipation sheet 500.

The display panel 100 can be a rigid display panel, but is not limited thereto. The display panel 100 can be a flexible display panel of which shape can be deformed, such as a foldable, bendable, rollable, or stretchable display panel.

The display panel 100 can include a first long edge LE1, a second long edge LE2, a first short edge SE1, and a second short edge SE2 that form an edge of the display panel 100.

The first long edge LE1 and the second long edge LE2 can extend in a first direction DR1, and the first short edge SE1 and the second short edge SE2 can extend in a direction between the first direction DR1 and a second direction DR2. The first long edge LE1 and the second long edge LE2 can have both ends connected through the first short edge SE1 and the second short edge SE2.

The first long edge LE1 can be disposed at one side of the second long edge LE2 in the second direction DR2. The first long edge LE1 and the second long edge LE2 can extend in parallel, but are not limited thereto.

A length of the first long edge LE1 can be shorter than a length of the second long edge LE2. Accordingly, the first short edge SE1 and the second short edge SE2 can extend in an intersecting direction, but are not limited thereto.

The first direction DR1 and the second direction DR2 can be directions intersecting each other. The first direction DR1 and the second direction DR2 can be orthogonal, but are not limited thereto. The first direction DR1 and the second direction DR2 are provided to clarify the description of the invention, the first direction DR1 and the second direction DR2 are relative, and the embodiments of the present disclosure are not limited thereto.

In a plan view, the first long edge LE1 can be disposed above the display area DA, and the second long edge LE2 can be disposed below the display area DA.

In a plan view, the first short edge SE1 can be disposed at the right side of the display area DA, and the second short edge SE2 can be disposed at the left side of the display area DA.

The display panel 100 can include a first notch NCP1 and a second notch NCP2 that are recessed (or curved). Each of the first notch NCP1 and the second notch NCP2 can be recessed in a direction from a side surface of the display panel 100 toward the other surface.

The first notch NCP1 can be formed at the first long edge LE1. For example, the first long edge LE1 can entirely extend in the first direction DR1, but can include the first notch NCP1 that is recessed from the first long edge LE1 toward the second long edge LE2.

The second notch NCP2 can be formed at the second long edge LE2. For example, the second long edge LE2 can entirely extend in the first direction DR1, but can include the second notch NCP2 that is recessed from the second long edge LE2 toward the first long edge LE1.

The flat surface shapes of the polarization layer 200 disposed above the display panel 100 and the back plate 400 and the heat dissipation sheet 500 that are disposed below the display panel 200 can correspond to the flat surface shape of the display panel 100, but are not limited thereto.

When the display panel 100 includes the first notch NCP1 and the flat surface shapes of the polarization layer 200, the back plate 400, and the heat dissipation sheet 500 correspond to the flat surface shape of the display panel 100, a sensor 10 can be disposed in an area in which the first notch NCP1 is formed in a plan view. Accordingly, the display apparatus 1 can perform various roles and functions by sensing external light as well as displaying a screen.

Since the display panel 100 includes the second notch NCP2, components, such as a handle of a driver's seat, can be disposed on the corresponding portion and the display area DA capable of displaying the screen can be maximized, thereby improving a user's convenience and improving aesthetic feeling.

However, the flat surface shape of the display panel 100 is not limited thereto and can vary according to a design and an arrangement location.

The display panel 100 can include the display area DA and the non-display area NDA.

The display area DA can correspond to the shape of the display panel 100, but is not limited thereto.

The display apparatus can include a plurality of pixels PXs. The plurality of pixels PXs can be disposed in the display area DA. The plurality of pixels PXs can be repeatedly disposed in the first direction DR1 and the second direction DR2 in the display area DA.

The non-display area NDA can be disposed around the display area DA to surround the display area DA, but is not limited thereto.

The non-display area NDA can include a first non-display area NDA1 disposed along the first long edge LE1, the first short edge SE1, and the second short edge SE2, and a second non-display area NDA2 disposed along the second long edge LE2. The second non-display area NDA2 can be disposed along the second long edge LE2 including the curved second notch NCP2.

The first non-display area NDA1 can be disposed at one side and the other side of the display area DA in the first direction DR1 and disposed at one side of the display area DA in the second direction DR2.

The second non-display area NDA2 can include a notch non-display area N_NDA disposed around the second notch NCP2, and an extension non-display area E_NDA disposed around the notch non-display area N_NDA.

The extension non-display area E_NDA can extend from the notch non-display area N_NDA in the first direction DR1. The extension non-display area E_NDA can be disposed between the notch non-display area N_NDA and the first non-display area NDA1. The extension non-display area E_NDA can connect the notch non-display area N_NDA to the first non-display area NDA1.

The polarization layer 200 can be disposed on the display panel 100. The polarization layer 200 can be disposed above the display panel 100.

The polarization layer 200 can polarize light emitted from the display panel 100 at a polarization angle. The polarization layer 200 can emit light polarized at the polarization angle to the outside. The polarization layer 200 can include a function of blocking the reflection of light excluding the light polarized at the polarization angle among external light.

The polarization layer 200 can include a first phase delay layer, a second phase delay layer on the first phase delay layer, and a polarization layer on the second phase delay layer, but the embodiments of the present disclosure are not limited thereto.

Accordingly, the polarization layer 200 can improve the visibility of the display apparatus 1.

In FIG. 3, although an example in which the polarization layer 200 and the display panel 100 are separated from each other is shown, the embodiments of the present disclosure are not limited thereto, and the polarization layer 200 can be included in the display panel 100.

The cover layer 300 can be disposed on the polarization layer 200. The cover layer 300 can be disposed above the polarization layer 200.

The cover layer 300 can be disposed at the outermost edge of the display apparatus 1 and can cover the stacked members below the cover layer 300. Accordingly, the cover layer 300 can protect members (e.g., the display panel 100) disposed below the cover layer 300 from the outside.

Although the cover layer 300 can be formed of a glass material including glass or quartz, the embodiments of the present disclosure are not limited thereto. The cover layer 300 can be a cover layer formed by chemical reinforcement, but the embodiments of the present disclosure are not limited thereto. The cover layer 300 can be a cover window, a window cover, or a cover member, but the embodiments of the present disclosure are not limited thereto. The embodiments of the present disclosure are not limited thereto.

The cover layer 300 can be formed of a glass material, and in this case, the cover layer 300 can be damaged by an external force, resulting in glass fragments. To prevent the shattering of the glass fragments due to the damage to the cover layer 300 or increase the durability of the cover layer 300, the display apparatus 1 can further include at least one additional layer on the cover layer 300.

The back plate 400 can be disposed on the display panel 100. The back plate 400 can be disposed below the display panel 100.

Since the display panel 100 is too thin, the back plate 400 can be attached to a back surface of the display panel 100 to increase the strength and/or rigidity of the display panel 100. The back plate 400 can be formed of a thin film formed of a combination of polyethylene naphthalate (PEN), polyethylene terephthalate (PET), polyethylene ether phthalate, polycarbonate, polyarylate, polyether imide, polyether sulfonate, polyimide, polyacrylate, or other suitable polymers.

However, the embodiments of the present disclosure are not limited thereto, and other suitable materials that can be used to form the back plate 400 can be thin glass, a metal foil shielded with a dielectric, a multilayered polymer, a polymer film containing a polymer material combined with nano particles or micro particles, etc.

In addition, the back plate 400 can prevent static electricity generation through surface electrification treatment.

The heat dissipation sheet 500 can be disposed above the back plate 400. The heat dissipation sheet 500 can be disposed below the back plate 400.

The heat dissipation sheet 500 can be formed of a material with high thermal conductivity, such as a metal. The embodiments of the present disclosure are not limited thereto, but, for example, the heat dissipation sheet 500 can include a metal with excellent thermal conductivity, such as aluminum or an aluminum alloy. The heat dissipation sheet 500 can discharge heat generated during the driving of the display panel 100 to the outside, thereby decreasing a temperature of the display apparatus 1.

In addition, the heat dissipation sheet 500 can be formed of a material with high strength, thereby securing the rear rigidity of the display apparatus 1 and protecting the display apparatus 1 from an external impact.

The adhesive layer 700 can include first to fourth adhesive layers 710, 720, 730, and 740. Each of the first to fourth adhesive layers 710, 720, 730, and 740 can be disposed between the display panel 100, the polarization layer 200, the cover layer 300, the back plate 400, and the heat dissipation sheet 500.

Each of the first to fourth adhesive layers 710, 720, 730, and 740 can be transparent and can include a material with high adhesion. For example, each of the first to fourth adhesive layers 710, 720, 730, and 740 can be a transparent material, such as an optical clear adhesive (OCA) or a pressure sensitive adhesive (PSA), but is not limited thereto.

The adhesive layer 700 can serve to reduce diffused reflection of external light to improve a contrast ratio.

The first adhesive layer 710 can be disposed between the display panel 100 and the polarization layer 200 and can mutually adhere the display panel 100 and the polarization layer 200.

The second adhesive layer 720 can be disposed between the polarization layer 200 and the cover layer 300 and can mutually adhere the polarization layer 200 and the cover layer 300.

The third adhesive layer 730 can be disposed between the display panel 100 and the back plate 400 and can mutually adhere the display panel 100 and the back plate 400.

The fourth adhesive layer 740 can be disposed between the back plate 400 and the heat dissipation sheet 500 and can mutually adhere the back plate 400 and the heat dissipation sheet 500.

The display apparatus 1 can further include the sensor 10 and a blocking member 600.

The sensor 10 can be disposed in the non-display area NDA. The sensor 10 can be disposed in an area corresponding to the first notch NCP1 of the display panel 100 in the non-display area NDA in a plan view, but the arrangement location of the sensor 10 is not limited thereto. The sensor 10 can be disposed at various locations in the non-display area NDA. For example, the sensor 10 can be disposed around the display area DA in the non-display area NDA. The arrangement location of the sensor 10 can be disposed at various locations according to a design and purpose.

The sensor 10 does not overlap the display panel 100 and can be disposed below the display panel 100. The sensor 10 may not overlap the polarization layer 200, the back plate 400, the heat dissipation sheet 500, and the adhesive layer 700, but is not limited thereto.

The display apparatus 1 can include at least one sensor 10. In the drawing, only one sensor 10 is illustrated as being disposed, but the embodiments of the present disclosure are not limited thereto. The sensor 10 can be provided as a plurality of sensors.

In a top view of the display apparatus 1, the sensor 10 can be covered by the cover layer 300 and can be invisible. However, the sensor 10 is illustrated in FIG. 1 in order to describe the size, location, number, etc. of the sensor 10 that can be disposed.

The sensor 10 can sense external light incident after passing through the display panel 100. The sensor 10 can sense external light that is incident on the display apparatus 1, passes through the display panel 100, and reaches the sensor 10.

The sensor 10 can perform various operations and functions by sensing external light that reaches the sensor 10 after passing through the display panel 100. For example, the sensor 10 can perform a function of sensing external light to adjust the illuminance of the display panel 100, perform a camera function, or perform a function of detecting infrared rays (IR) among external light to recognize faces of a driver and a co-driver, detecting infrared rays (IR) among external light to recognize an iris of a driver or a co-driver, etc.

However, functions of the sensor 10 are not limited thereto, and other functions that are possible by sensing external incident light can also be performed.

The blocking member 600 can directly or indirectly prevent external light and heat from penetrating the display panel 100. For example, the blocking member 600 can directly or indirectly prevent light and heat emitted from the sensor 10 from penetrating the display panel 100.

At least a part of the blocking member 600 can be disposed between the sensor 10 and the display panel 100. The blocking member 600 can be disposed in the non-display area NDA. The blocking member 600 can be disposed around an area in which the sensor 10 is disposed in a plan view. The blocking member 600 can be disposed between the sensor 10 and the display panel 100 in a plan view.

The blocking member 600 may not overlap the display panel 100, the polarization layer 200, the back plate 400, the heat dissipation sheet 500, and the adhesive layer 700. The blocking member 600 may not overlap the sensor 10, but is not limited thereto, and a part of the blocking member 600 can overlap the sensor 10.

For example, the blocking member 600 can be disposed in the area in which the first notch NCP1 is formed in a plan view. In FIG. 1, the blocking member 600 is illustrated as being disposed only in the area in which the first notch NCP1 is formed, but is not limited thereto, and can be disposed to further extend outward from the area in which the first notch NCP1 is formed.

Accordingly, it is possible to minimize the arrangement area of the blocking member 600, thereby simplifying a process and minimizing the cost and time required for the process.

The blocking member 600 can cover the side surface of the display panel 100. In addition, the blocking member 600 can further cover side surfaces of at least one of the polarization layer 200, the back plate 400, the heat dissipation sheet 500, and the adhesive layer 700.

The blocking member 600 can be disposed on the side surface of the display panel 100. The blocking member 600 can be disposed to come into direct contact with the side surface of the display panel 100.

The blocking member 600 can be disposed on the side surfaces of the polarization layer 200, the back plate 400, the heat dissipation sheet 500, and the adhesive layer 700. The blocking member 600 can be disposed to come into direct contact with the side surfaces of the polarization layer 200, the back plate 400, the heat dissipation sheet 500, and the adhesive layer 700.

The blocking member 600 can overlap the cover layer 300. The blocking member 600 can come into direct contact with the cover layer 300, but is not limited thereto. The blocking member 600 can come into direct contact with a lower surface (or a back surface) of the cover layer 300. The lower surface of the cover layer 300 can refer to a surface facing the polarization layer 200.

A thickness TH of the blocking member 600 can be 1 mm, can range from 0.5 mm to 2 mm, or range from 0.1 mm to 5 mm. When the thickness TH of the blocking member 600 is larger than the above range, the blocking member 600 can be visible in the bezel area of the display apparatus 1, and when the thickness TH of the blocking member 600 is smaller than the above range, the blocking member 600 cannot smoothly perform the role of blocking heat and/or light. For example, when the thickness TH of the blocking member 600 is within the above range, external heat and light can be smoothly blocked without being visible from the outside.

The blocking member 600 can be formed of a resin including a material with low thermal conductivity. The embodiments of the present disclosure are not limited thereto, but, for example, the blocking member 600 can include at least one selected from urethane, phenol, etc. that are materials with low thermal conductivity.

The thermal conductivity of the blocking member 600 can range from 0.02 to 0.025 W/mK or range from 0.01 to 0.04 W/mK. When the thermal conductivity of the blocking member 600 is more than the above range, it can be difficult to block external heat, and when the thermal conductivity of the blocking member 600 is less than the above range, it can be difficult to form the blocking member 600. For example, when the thermal conductivity of the blocking member 600 is within the above range, external heat can be blocked more easily.

The blocking member 600 can be formed of a white-based color. Accordingly, the blocking member 600 can more easily reflect and block external light.

Since the display apparatus 1 includes the blocking member 600, it is possible to suppress or prevent the light and/or heat emitted from the sensor 10 from entering the display panel 100 and prevent damage to the display panel 100.

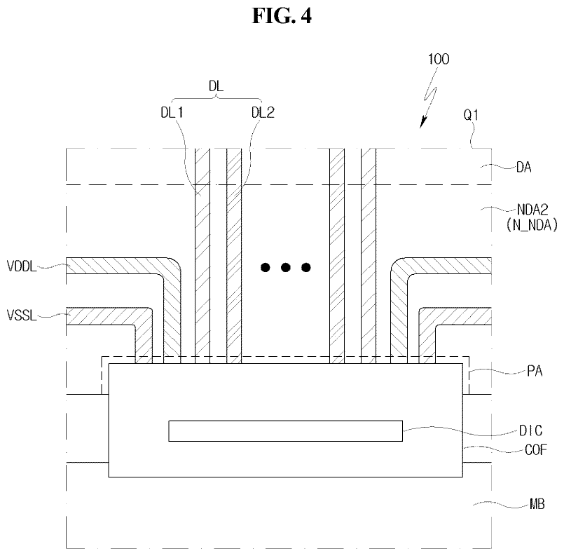

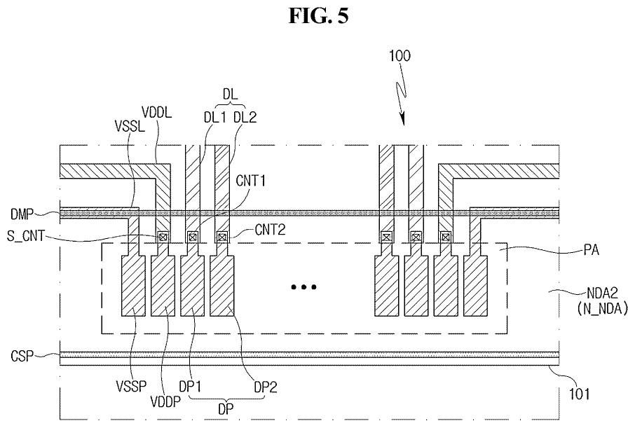

FIG. 4 is an enlarged view of area Q1 in FIG. 3. FIG. 5 is a view illustrating a display panel of FIG. 4.

FIG. 5 is a view of FIG. 4 from which a flexible film COF, a main board MB, and a drive IC DIC are omitted except for the display panel 100. In FIG. 4, for convenience of description, ratios between components are adjusted.

Referring to FIGS. 3 to 5, the display apparatus 1 can further include a pad area PA, a gate driving unit GIP, the main board MB, the flexible film COF, the drive IC DIC, a gate line GL, a gate control line GCL, a data line DL, a low-potential voltage line VSSL, and a high-potential voltage line VDDL.

The pad area PA can overlap the flexible film COF. The pad area PA can be attached to the flexible film COF. For example, the display panel 100 and the flexible film COF can be attached through the pad area PA.

The pad area PA can be disposed in the non-display area NDA. The pad area PA can be disposed in the second non-display area NDA2. The pad area PA can be disposed in each of the notch non-display area N_NDA and the extension non-display area E_NDA.

The pad area PA can include a plurality of pads. The pad area PA can include a low-potential voltage pad VSSP, a high-potential voltage pad VDDP, a first data pad DP1, and a second data pad DP2. The low-potential voltage pad VSSP, the high-potential voltage pad VDDP, the first data pad DP1, and the second data pad DP2 can be disposed in the pad area PA.

In FIG. 5, the low-potential voltage pad VSSP, the high-potential voltage pad VDDP, the first data pad DP1, and the second data pad DP2 are illustrated as being disposed sequentially, but are not limited thereto. For example, the first data pad DP1 and the second data pad DP2 can be disposed between the low-potential voltage pad VSSP and the high-potential voltage pad VDDP.

However, the embodiments of the present disclosure are not limited thereto, and the pad area PA disposed in an area that overlaps the flexible films COFs disposed at both ends among the flexible films COFs disposed along the non-display area NDA can further include a gate control pad.

The gate driving unit GIP can be disposed in the non-display area NDA. The gate driving unit GIP can be disposed at at least one of one side and the other side of the display area DA in the first direction DR1, but is not limited thereto. In a plan view, the gate driving unit GIP can be disposed at the left side and the other side of the display area DA.

The gate driving unit GIP can include a plurality of transistors. The transistors disposed in the gate driving unit GIP can be connected to a sub-pixel SP (or a pixel) through the gate line GL. The gate driving unit GIP can apply a gate signal to each sub-pixel SP (or each pixel) through the gate line GL.

The gate driving unit GIP can receive a gate control signal from the drive IC DIC through the gate control line GCL. The gate driving unit GIP can generate a scan signal and a light-emitting signal (or a light-emitting control signal) based on the gate control signal. The gate driving unit GIP can include a scan driver and a light-emitting signal driver. The scan driver can generate a scan signal in a row-sequential manner and supply the scan signal to the scan lines in order to drive one or more scan lines connected to each sub-pixel SP (or each pixel) row. The light-emitting signal driver can generate a light-emitting signal in a row-sequential manner and supply the light-emitting signal to light-emitting signal lines in order to drive one or more light-emitting signal lines connected to each sub-pixel SP (or each pixel) row.

The main board MB can be connected to the display panel 100 through the flexible film COF. The main board MB can be electrically connected to the sub-pixel SP (or the pixel) of the display area DA through the flexible film COF. The main board MB can be electrically connected to the flexible film COF. The main board MB and the flexible film COF can be electrically connected through the plurality of pads VSSP, VDDP, and DP.

The main board MB can have various types of components for supplying various signals, such as a gate control signal, a driving signal, a data signal, etc., to the drive IC DIC. The main board MB can be a printed circuit board, but is not limited thereto.

The main board MB can be connected to the display panel 100 through the flexible film COF in the second non-display area NDA2. The main board MB can be provided as a plurality of main boards along the second non-display area NDA2, but is not limited thereto. The number of main boards MBs can vary according to a design.

At least one of the main boards MBs can be disposed around the second notch NCP2 and connected to the display panel 100 through the flexible film COF in the notch non-display area N_NDA.

The flexible film COF can be connected to the display panel 100 and the main board MB. The flexible film COF can be attached to each of the display panel 100 and the main board MB and electrically connected to each of the display panel 100 and the main board MB. For example, the display panel 100 and the main board MB can be electrically connected through the flexible film COF. The flexible film COF can be provided as a plurality of flexible films, but is not limited thereto.

The flexible film COF can be attached to the display panel 100 in the second non-display area NDA2. The flexible film COF can be repeatedly disposed along the second non-display area NDA. The flexible film COF can be attached to the display panel 100 across the notch non-display area N_NDA and the extension non-display area E_NDA.

A single main board MB can be electrically connected to the display panel 100 through at least one flexible film COF. For example, the main boards MBs disposed at both ends among the plurality of main boards MBs disposed along the second non-display area NDA2 can be electrically connected to the display panel 100 through one flexible film COF, and the remaining main boards MBs can be electrically connected to the display panel 100 through two flexible films COFs.

The flexible film COF can be electrically connected to the pad area PA. Accordingly, the flexible film COF can supply a gate control signal, driving signals, power voltages, data voltages, etc. to the plurality of sub-pixels SPs (or the pixels) and the gate driving unit GIP that are disposed in the display area DA.

The flexible film COF can be a flexible insulating film including a plurality of conductive lines. The flexible film COF can include, for example, polycarbonate, polyethylene terephthalate, polyimide, polyamide, polyester, polyacrylate, polymethyl methacrylate, etc., but is not limited thereto.

The drive IC DIC can be mounted on the flexible film COF. The drive IC DIC can be disposed by a method of a chip on glass, a chip on film, a tape carrier package, etc. according to a mounting method. In the present disclosure, the drive IC DIC is described as being mounted on the flexible film COF by the chip on film method, but is not limited thereto.

The drive IC DIC can drive the display apparatus 1. The drive IC DIC can process data signals for displaying a video, various driving signals for processing the data signals, etc. The drive IC DIC can include a gate driver IC, a data driver IC, etc.

Although not illustrated, the display apparatus 1 can further include a low dropout (LDO) regulator and a level shifter. The LDO regulator and the level shifter can be disposed on the main board MB, but are not limited thereto.

The drive IC DIC can be electrically connected to the LDO regulator and the level shifter and can transmit signals generated by the LDO regulator and the level shifter to the gate driving unit GIP.

The gate line GL can extend from the gate driving unit GIP and can be connected to the sub-pixel SP (or the pixel). The gate line GL can electrically connect the gate driving unit GIP to the sub-pixel SP (or the pixel). The gate line GL can apply a gate signal to each sub-pixel SP (or the pixel) from the gate driving unit GIP.

The gate control line GCL can be disposed in the non-display area NDA. The gate control line GCL can extend from the pad area PA to the gate driving unit GIP and can be electrically connected to the gate driving unit GIP.

The gate control line GCL can be provided as a plurality of gate control lines, and the plurality of gate control lines GCLs can supply at least two different signals.

The gate control line GCL can apply the gate control signal to the gate driving unit GIP. The gate control signal can be transmitted from the main board MB or the drive IC DIC. The gate control line GCL can electrically connect the gate driving unit GIP to the main board MB or the drive IC DIC.

The gate control line GCL can be electrically connected to the flexible film COF disposed at both ends among the plurality of flexible films COFs connected to the display panel 100 along the second non-display area NDA2. The gate control line GCL can be disposed at the outermost edge among a plurality of lines connected to one flexible film COF, but is not limited thereto.

The data line DL can extend from the pad area PA and can be connected to the sub-pixel SP (or the pixel) of the display area DA. The data line DL can apply a data signal to each sub-pixel SP (or each pixel). The data signal can be applied from the main board MB or the drive IC DIC. The data line DL can electrically connect the sub-pixel SP (or the pixel) to the main board MB or the drive IC DIC.

The data line DL can include a first data line DL1 and a second data line DL2. The data line DL can be connected to the data pads DP1 and DP2. The first data line DL1 can be electrically connected in contact with the first data pad DP1 through a first data contact hole CNT1. The second data line DL2 can be electrically connected in contact with the second data pad DP2 through a second data contact hole CNT2.

The low-potential voltage line VSSL can be disposed in the non-display area NDA to surround the display area DA. The low-potential voltage line VSSL can be disposed in the non-display area NDA with the display area DA and the gate driving unit GIP interposed therebetween. For example, the gate driving unit GIP can be disposed between the display area DA and the low-potential voltage line VSSL.

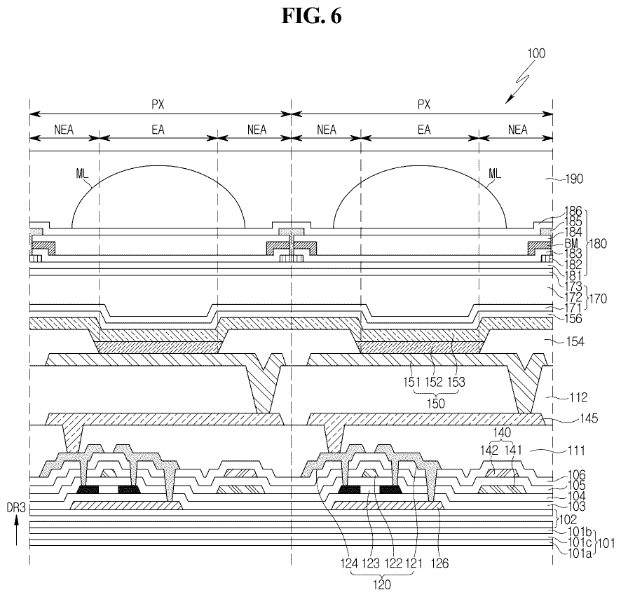

The low-potential voltage line VSSL can apply a low-potential voltage to the sub-pixel SP (or the pixel). The low-potential voltage line VSSL can be electrically connected to the cathode electrode 153 (see FIG. 6) of the sub-pixel SP (or the pixel) to apply a low-potential voltage.

The low-potential voltage line VSSL can be connected to the pad area PA. The low-potential voltage line VSSL can be physically connected to the low-potential voltage pad VSSP and electrically connected to the low-potential voltage pad VSSP. The low-potential voltage line VSSL and the low-potential voltage pad VSSP can be formed integrally, but are not limited thereto.

The high-potential voltage line VDDL can be disposed between the display area DA and the low-potential voltage line VSSL in the non-display area NDA. The high-potential voltage line VDDL can further include a high-potential connection electrode. The high-potential connection electrode can be disposed on a different layer from the high-potential voltage line VDDL. For example, the high-potential connection electrode can be disposed between a second insulating layer 104 and a third insulating layer 105. The high-potential connection electrode can electrically connect the high-potential voltage line VDDL to an anode electrode 151 (see FIG. 6) across lines disposed on the same layer as the high-potential voltage line VDDL.

The high-potential connection electrode can be electrically connected to the anode electrode 151 (see FIG. 6) across the lines disposed on the same layer as the high-potential voltage line VDDL.

The high-potential voltage line VDDL can apply a high-potential voltage to the sub-pixel SP (or the pixel). The high-potential voltage line VDDL can be electrically connected to the anode electrode 151 (see FIG. 6) of the sub-pixel SP (or the pixel) to apply a high-potential voltage.

The high-potential voltage line VDDL can be connected to the pad area PA. The high-potential voltage line VDDL can be physically connected to the high-potential voltage pad VDDP and electrically connected to the high-potential voltage pad VDDP. The high-potential voltage line VDDL can come into contact with the high-potential voltage pad VDDP by the high-potential voltage pad VDDP.

However, the embodiments of the present disclosure are not limited thereto, and the high-potential voltage line VDDL can be disposed on the same layer as the high-potential voltage pad VDDP and formed integrally with the high-potential voltage pad VDDP. For example, the high-potential voltage line VDDL can be formed of the same material and the same conductive layer as the high-potential voltage pad VDDP, and the high-potential voltage line VDDL and the high-potential voltage pad VDDP are formed together by the same mask process.

Even in this case, the high-potential connection electrode disposed on a different layer from the high-potential voltage pad VDDP can be further included. The high-potential connection electrode can electrically connect the high-potential voltage line VDDL to the anode electrode 151 (see FIG. 6) across the lines disposed on the same layer as the high-potential voltage line VDDL.

The display apparatus 1 can further include a dam part DMP. The dam part DMP can be disposed in the non-display area NDA. The dam part DMP can be disposed to surround the display area DA, but is not limited thereto. The dam part DMP can be disposed to overlap at least a part of the low-potential voltage line VSSL. The dam part DMP can be disposed between the display area DA and the pad area PA in the second non-display area NDA2.

Hereinafter, a cross-sectional structure of the display area DA of the display panel 100 including the pixels PXs will be described with reference to FIG. 6.

FIG. 6 is a cross-sectional view of a pixel of the display panel according to one embodiment of the present disclosure.

A cross section of the pixel PX disposed in the display area DA will be described with reference to FIGS. 3 and 6.

Referring to FIGS. 3 and 6, the display panel 100 can include a substrate 101, a thin film transistor 120, a storage electrode 140, a light-emitting part 150, an encapsulation part 170, and a touch part 180 in the display area DA. However, the embodiments of the present disclosure are not limited thereto.

The substrate 101 can provide a space in which various components can be disposed thereon. The substrate 101 can correspond to the flat surface shape of the display panel 100 of FIG. 3. For example, the substrate 101 can include the first notch NCP1 and the second notch NCP2. The substrate 101 can include the display area DA and the non-display area NDA of the display panel 100 in substantially the same manner.

The substrate 101 can include one or more plastic materials, but is not limited thereto, and can include a glass material.

The substrate 101 can be a multi-substrate including a plurality of substrates of a first substrate 101a, a second substrate 101b, and a third substrate 103c each including a plastic material, such as polyimide, but the embodiments of the present disclosure are not limited thereto. For example, the substrate 101 can be a single substrate formed of a single layer.

The substrate 101 can include a rigid substrate. However, the embodiments of the present disclosure are not limited thereto, and the substrate 101 can include a flexible substrate.

The buffer layer 102 can be disposed on the substrate 101. The buffer layer 102 can minimize or delay the diffusion of moisture or oxygen permeating the substrate 101. Although the buffer layer 102 can be formed by alternately stacking silicon nitride (SiNx) and silicon oxide (SiOx) at least once, the embodiments of the present disclosure are not limited thereto.

Although the disclosure describes that the buffer layer 102 is formed as multiple layers formed of three layers, the number of layers forming the buffer layer 102 is not limited thereto, and the buffer layer 102 can be formed as a single layer.

A light shielding layer 126 can be disposed on the buffer layer 102. The light shielding layer 126 can prevent light from being transmitted to a semiconductor layer 123 of the thin film transistor 120. For example, the semiconductor layer 123 can be disposed to overlap the light-shielding layer 126. The light shielding layer 126 can be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

A first insulating layer 103 can be disposed on the light shielding layer 126. The first insulating layer 103 can prevent a short circuit between a component of the thin film transistor 120 and the light shielding layer 126. The first insulating layer 103 can be formed of the same material as the buffer layer 102, but the embodiments of the present disclosure are not limited thereto. For example, the first insulating layer 103 can be formed of an inorganic material, such as silicon nitride (SiNx) or silicon oxide (SiOx), but the embodiments of the present disclosure are not limited thereto.

The thin film transistor 120 can be disposed on the first insulating layer 103. The thin film transistor 120 can include a source electrode 121, a gate electrode 122, a semiconductor layer 123, and a drain electrode 124.

The semiconductor layer 123 can be disposed on the first insulating layer 103. The semiconductor layer 123 can include a metal oxide semiconductor, such as indium-gallium-zinc oxide (IGZO), and a silicon-based semiconductor material, such as amorphous silicon or polycrystalline silicon, but the embodiments of the present disclosure are not limited thereto. The semiconductor layer 123 can include a source area, a drain area, and a channel area between the source area and the drain area.

Since the polycrystalline semiconductor layer has higher mobility than the amorphous semiconductor layer and the oxide semiconductor layer, consumed power can be less, and reliability can be excellent. Accordingly, a driving transistor can be formed of a polycrystalline semiconductor layer, but the embodiments of the present disclosure are not limited thereto.

A second insulating layer 104 can be disposed on the semiconductor layer 123. The second insulating layer 104 can be formed of the same material as the first insulating layer 103, but the embodiments of the present disclosure are not limited thereto. The second insulating layer 104 can prevent a short circuit between the semiconductor layer 123 and another component of the thin film transistor 120.

The gate electrode 122 can be disposed on the second insulating layer 104. The gate electrode 122 can be disposed on the second insulating layer 104 to overlap the channel area of the semiconductor layer 123. The gate electrode 122 can be formed of a single layer or multiple layers made of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto. The gate electrode 122 can be disposed along with the gate line, but the embodiments of the present disclosure are not limited thereto.

A third insulating layer 105 can be disposed on the gate electrode 122. The third insulating layer 105 can be formed of the same material as the first insulating layer 103 or the second insulating layer 104, but the embodiments of the present disclosure are not limited thereto.

The storage electrode 140 can be disposed to be spaced apart from the thin film transistor 120. The storage electrode 140 can include a first storage electrode 141 and a second storage electrode 142.

The first storage electrode 141 can be formed of the same material as the gate electrode 122 and formed on the same layer, but the embodiments of the present disclosure are not limited thereto.

The second storage electrode 142 can be disposed on the first storage electrode 141. The second storage electrode 142 can be disposed on the third insulating layer 105, and the third insulating layer 105 between the first storage electrode 141 and the second storage electrode 142 can be used as a dielectric to generate a capacitance. The second storage electrode 142 can be formed of the same material as the first storage electrode 141, but the embodiments of the present disclosure are not limited thereto.

A fourth insulating layer 106 can be disposed on the second storage electrode 142. The fourth insulating layer 106 can be formed of the same material as the first insulating layer 103, the second insulating layer 104, or the third insulating layer 105, but the embodiments of the present disclosure are not limited thereto.

The source electrode 121 and the drain electrode 124 can be disposed on the fourth insulating layer 106.

The source electrode 121 and the drain electrode 124 can be electrically connected to the semiconductor layer 123 through contact holes. The source electrode 121 and the drain electrode 124 can be formed of a metallic material. For example, the source electrode 121 and the drain electrode 124 can be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The source electrode 121 and the drain electrode 124 can be disposed along with the data line. For example, the data line can be formed of the same material as the source electrode 121 and the drain electrode 124 and formed on the same layer, but the embodiments of the present disclosure are not limited thereto.

The thin film transistor 120 can be a driving transistor, and although not illustrated, the display panel 100 can further include a switching transistor, but the embodiments of the present disclosure are not limited thereto.

A first protective layer 111 can be disposed on the source electrode 121 and the drain electrode 124.

The first protective layer 111 can planarize an upper portion of the thin film transistor 120 and protect the thin film transistor 120. The first protective layer 111 can be formed of an organic material. For example, the first protective layer 111 can be formed of an organic material containing an acrylic resin, an epoxy resin, a phenolic resin, a polyamide resin, or a polyimide resin, but the embodiments of the present disclosure are not limited thereto.

A second protective layer 112 can be disposed on the first protective layer 111. The second protective layer 112 can be formed of the same material as the first protective layer 111, but the embodiments of the present disclosure are not limited thereto.

A connection electrode 145 can be disposed between the first protective layer 111 and the second protective layer 112.

The connection electrode 145 can electrically connect the thin film transistor 120 to the light-emitting part 150. The connection electrode 145 can be formed of the same material as the source electrode 121 and the drain electrode 124, but the embodiments of the present disclosure are not limited thereto.

The connection electrode 145 can come into contact with the drain electrode 124 through the contact hole formed in the first protective layer 111 and can be electrically connected to the drain electrode 124.

The connection electrode 145 can be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 can be disposed on the second protective layer 112. The light-emitting part 150 can include an anode electrode 151, an organic layer 152, and a cathode electrode 153.

The anode electrode 151 can be disposed on the second protective layer 112. The anode electrode 151 can be electrically connected to the thin film transistor 120 through contact holes formed in the first protective layer 111 and the second protective layer 112.

The anode electrode 151 can be a reflective electrode that reflects light, but the embodiments of the present disclosure are not limited thereto. The anode electrode 151 can include a metal material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy and can be formed of a single layer or multiple layers, but the embodiments of the present disclosure are not limited thereto.

For example, the cathode electrode 153 can include a material, such as indium tin oxide (ITO) or indium zinc oxide (IZO), but the embodiments of the present disclosure are not limited thereto.

The organic layer 152 can be disposed on the anode electrode 151. The organic layer 152 can include one or more light-emitting structures (or light-emitting elements or elements) stacked on the anode electrode 151 in the order or reverse order of a hole transfer layer and an electron transfer layer. For example, the hole transfer layer can include a hole transporting layer, a hole injecting layer, an electron blocking layer, a p-type charge generation layer, etc., but the embodiments of the present disclosure are not limited thereto. For example, the electron transfer layer can include an electron transporting layer, an electron injecting layer, a hole blocking layer, an n-type charge generation layer, etc., but the embodiments of the present disclosure are not limited thereto.

The organic layer 152 can be an organic light-emitting layer, an inorganic light-emitting layer, a quantum dot light-emitting layer, a micro light-emitting diode, a micro mini light-emitting diode, etc., but the embodiments of the present disclosure area not limited thereto. For example, the organic layer 152 of the display panel 100 according to one embodiment of the present disclosure can include the organic light-emitting layer. The organic layer 152 can be a white light-emitting layer, but the embodiments of the present disclosure are not limited thereto. The organic layer 152 can be a white light-emitting layer, but the embodiments of the present disclosure are not limited thereto.

The cathode electrode 153 can be disposed on the organic layer 152. The cathode electrode 153 can be a transparent electrode that transmits light, but the embodiments of the present disclosure are not limited thereto. For example, the cathode electrode 153 can include a transparent conductive material, such as indium tin oxide (ITO) or indium zinc oxide (IZO), or a metal that transmits visible light, but the embodiments of the present disclosure are not limited thereto.

The capping layer 156 can be further disposed on the cathode electrode 153. The capping layer 156 can minimize damage to the cathode electrode 153 of the light-emitting element EL and the organic layers 152 located below the cathode electrode 153 from an external light source. The capping layer 156 can be formed of an organic or inorganic film.

The capping layer 156 can be disposed using a material, such as LiF etc., as an inorganic film and can further include an organic film, but the embodiments of the present disclosure are not limited thereto. For example, the capping layer 156 can be formed of the stacking structure of an organic film and an inorganic film, and a thickness of the organic film can differ from a thickness of the inorganic film. In this case, the thickness of the organic film can be larger than the thickness of the inorganic film. As another example, the capping layer 156 can be formed of two or more layers by stacking materials having different refractive indices. Accordingly, it is possible to increase the light efficiency of the display panel 100.

A bank 154 can be disposed to expose the anode electrode 151. The bank 154 can define an opening (or a light-emitting area EA) of the pixel PX and can be disposed to cover an edge of the anode electrode 151. The organic layer 152 can be disposed in the opening of the pixel PX. For example, the organic layer 152 can be disposed on the anode electrode 151 exposed by the bank 154.

However, the embodiments of the present disclosure are not limited thereto, and the organic layer 152 can be disposed both in the opening (the light-emitting area EA) of the pixel PX and on the bank 154. For example, the organic layer 152 can be disposed in the entirety of the display area DA of the display panel 100.

The bank 154 can be formed of a material containing black pigment, or an organic material, such as a benzocyclobutene resin, a polyimide resin, an acrylic resin, a photosensitive polymer, etc., but the embodiments of the present disclosure are not limited thereto. When the bank 154 is formed of a material containing black pigment or black dye, the bank 154 can be a black bank. When the bank 154 is formed of a material containing black pigment or black dye, it is possible to shield external light or light reflected from the outside, thereby further increasing the luminance of the display apparatus.

A spacer can be further disposed on the bank 154. The spacer can be formed of the same material as the bank 154, but the embodiments of the present disclosure are not limited thereto. The spacer can prevent sagging of a mask during a mask process, thereby suppressing or preventing defects, such as imprinting, scratching, etc., on the display panel 100.

The encapsulation part 170 can be disposed on the bank 154 or the light-emitting part 150. The encapsulation part 170 can include one or more insulating layers. For example, the encapsulation part 170 can include a first inorganic encapsulation layer 171, an organic encapsulation layer 172 formed on the first inorganic encapsulation layer 171, and a second inorganic encapsulation layer 173 formed on the organic encapsulation layer 172. The encapsulation part 170 can include one or more inorganic layers and one or more organic layers. For example, the first inorganic encapsulation layer 171 and the second inorganic encapsulation layer 173 can include an inorganic material, and the organic encapsulation layer 172 can include an organic material, but the embodiments of the present disclosure are not limited thereto.

The first inorganic encapsulation layer 171 and the second inorganic encapsulation layer 173 can be disposed to extend around the dam part DMP, and the organic encapsulation layer 172 can be ended inside the dam part DMP. For example, the organic encapsulation layer 172 can be disposed inside an area surrounded by the dam part DMP without extending beyond the dam part DMP.

The touch part 180 can be disposed on the encapsulation part 170. The touch part 180 can include a touch buffer layer 181, a first touch electrode 182, a first touch insulating layer 183, a black matrix BM, a second touch insulating layer 184, a second touch electrode 185, and a third touch insulating layer 186.

The touch buffer layer 181 can be disposed on the encapsulation part 170. For example, the touch buffer layer 181 can be disposed on the second inorganic encapsulation layer 173. The touch buffer layer 181 can be formed of the same material as the buffer layer 102, but the embodiments of the present disclosure are not limited thereto.

The first touch electrode 182 can be disposed on the touch buffer layer 181.

The first touch insulating layer 183 can be disposed on the first touch electrode 182. The first touch insulating layer 183 can be formed of silicon oxide (SiOx), silicon nitride (SiNx), or multiple layers thereof, but the embodiments of the present disclosure are not limited thereto.

The black matrix BM can be disposed on the first touch insulating layer 183. The black matrix BM can include materials capable of absorbing light. The black matrix BM can include a black pigment or dye, but is not limited thereto. The black matrix BM can prevent a defect, such as light leakage that can occur between the pixels PXs.

The second touch insulating layer 184 can be disposed on the black matrix BM. The second touch insulating layer 184 can include an organic insulating material. For example, the second touch insulating layer 184 can be formed of photo acryl, benzocyclobutene (BCB), polyimide (PI), or polyamide (PA), but is not limited thereto.

The second touch electrode 185 can be disposed on the second touch insulation layer 184. The second touch electrode 185 can come into contact with the first touch electrode 182 through a contact hole.

The first touch electrode 182 and the second touch electrode 185 can include a metallic material. For example, the first touch electrode 185 and the second touch electrode 182 can be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

One of the first touch electrode 182 and the second touch electrode 185 can include a function of detecting touch, and the other can include a function of driving touch, but the embodiments of the present disclosure are not limited thereto.

The third touch insulating layer 186 can be disposed on the second touch electrode 185. The third touch insulating layer 186 can be formed of the same material as the first touch insulating layer 183, but is not limited thereto.

A microlens ML can be disposed on the third touch insulating layer 186. The microlens ML can include a hemispherical or semi-cylindrical shape, but is not limited thereto. The shape of the microlens ML can vary according to the size, shape, etc. of the light-emitting area EA.

Each microlens ML can control a path of light emitted from each pixel PX. Each microlens ML can control the path of light emitted from each pixel PX in the same direction or different directions.

Accordingly, each pixel PX can display the same video, or each pixel PX can display different images and videos according to a viewing angle.

In addition, by arranging the microlens ML, it is possible to secure a wide viewing angle characteristic, increase luminance, and prevent light leakage by blocking leaked light and reflected light.

A lens protective layer 190 can be disposed on the microlens ML. The lens protective layer 190 can include an organic insulating material, but is not limited thereto. The lens protective layer 190 can protect the microlens ML by covering the microlens ML.

A refractive index of the lens protective layer 190 can be smaller than a refractive index of the microlens ML. Accordingly, due to a difference in refractive index between the microlens ML and the lens protective layer 190, light passing through the microlens ML can be prevented from being reflected toward the substrate 101.

When the display apparatus 1 includes the sensor 10, the plurality of pixels PXs of the display panel 100, which are disposed around the sensor 10, can be damaged by the sensor 10. However, when the blocking member 600 is disposed between the sensor 10 and the display panel 100, it is possible to suppress or prevent damage to the display panel 100 due to the sensor 10.

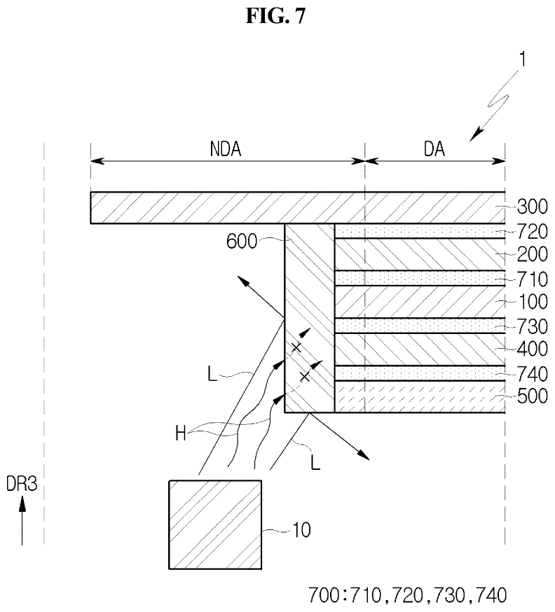

FIG. 7 is a schematic cross-sectional view of the display apparatus according to one embodiment of the present disclosure.

Referring to FIG. 7, the sensor 10 can emit at least one of light L and heat H. The blocking member 600 can block at least one of the light L and heat H emitted from the sensor 10 by covering the side surface of the display panel 100 around the sensor 10.

Specifically, by covering the side surface of the display panel 100, the blocking member 600 can suppress or prevent the light L and/or heat H emitted from the sensor 10 from directly penetrating the display panel 100.

By covering the side surfaces of the polarization layer 200, the back plate 400, the heat dissipation sheet 500, and the adhesive layer 700, the blocking member 600 can suppress or prevent the light L and/or heat H emitted from the sensor 10 from indirectly penetrating the display panel 100 through one of the polarization layer 200, the back plate 400, the heat dissipation sheet 500, and the adhesive layer 700.

A temperature of the display panel 100 can be suppressed or prevented from being increased by the light L and/or heat H emitted from the sensor 10.

Accordingly, it is possible to suppress or prevent damage to the display panel 100 due to the light L and/or heat H emitted from the sensor 10, thereby suppressing or preventing the risk of the life reduction and degradation of the display panel 100.

Furthermore, it is possible to increase the life of the display apparatus 1, reduce power consumption, and reduce production energy.

Hereinafter, other embodiments of the present disclosure will be described. For contents that are substantially the same as those described with reference to FIGS. 1 to 7 among components included in other embodiments, the same reference numerals are given, and overlapping contents can be omitted or briefly described.

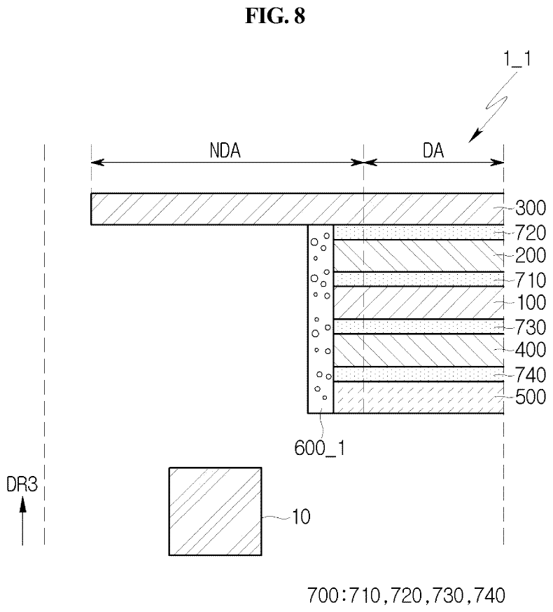

FIG. 8 is a cross-sectional view of a display apparatus according to another embodiment of the present disclosure.

Referring to FIG. 8, a display apparatus 1_1 according to the present embodiment can include a blocking member 600_1. The blocking member 600_1 can be formed of a foam tape.

The blocking member 600_1 can be formed of a material having low thermal conductivity and a foam tape, and the blocking member 600_1 can be formed in a white-based color. The material having low thermal conductivity can be at least one selected from, for example, urethane or phenol.

The blocking member 600_1 can cover the side surfaces of the display panel 100, the polarization layer 200, the back plate 400, the heat dissipation sheet 500, and the adhesive layer 700. The blocking member 600_1 may not overlap the display panel 100, the polarization layer 200, the back plate 400, the heat dissipation sheet 500, and the adhesive layer 700. The blocking member 600_1 can overlap the cover layer 300.

Even in this case, since the blocking member 600_1 is disposed, it is possible to suppress or prevent the light and/or heat emitted from the sensor 10 from entering the display panel 100 and prevent damage to the display panel 100.

Since the blocking member 600_1 is formed in the form of a foam tape, it is possible to simplify the manufacturing process of the display apparatus 1.

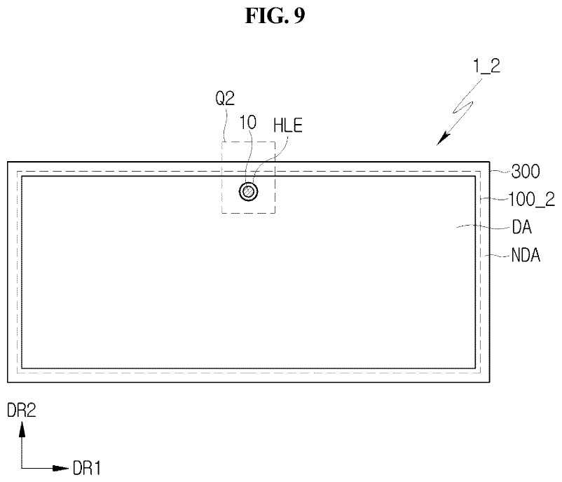

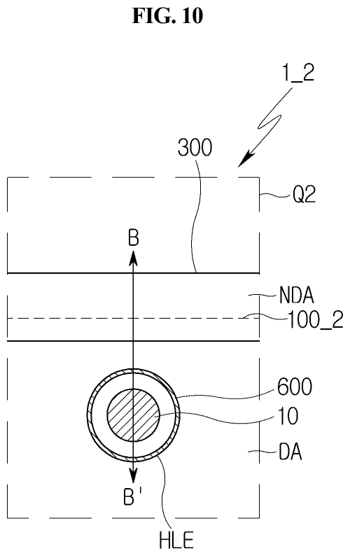

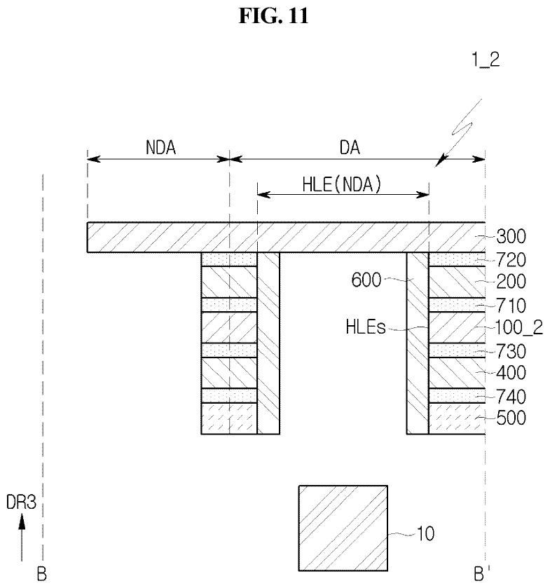

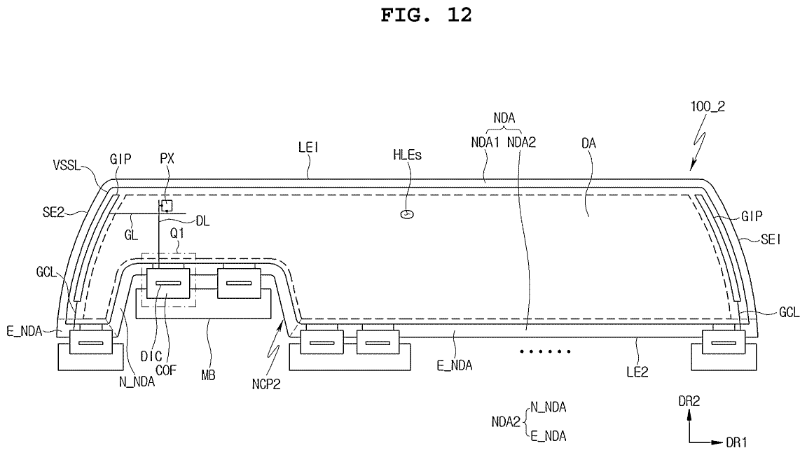

FIG. 9 is a plan view of a display apparatus according to still another embodiment of the present disclosure. FIG. 10 is an enlarged view of area Q2 in FIG. 9. FIG. 11 is a cross-sectional view along line B-B′ in FIG. 10. FIG. 12 is a plan view of a display panel according to still another embodiment of the present disclosure.

Referring to FIGS. 9 to 12, a display apparatus 1_2 according to the present embodiment can include a sensor hole HLE. The sensor 10 and the blocking member 600 can be disposed inside the sensor hole HLE in a plan view. The sensor 10 and the blocking member 600 can overlap the sensor hole HLE.

The sensor hole HLE can be defined by physically passing through a display panel 100_2, the polarization layer 200, the cover layer 300, the back plate 400, the heat dissipation sheet 500, and the adhesive layer 700 in a thickness direction (a third direction DR3). The cover layer 300 can cover the sensor hole HLE.

The display panel 100_2 does not include the first notch NCP1 (see FIG. 1) and can include the second notch NCP2 and a sub-hole HLEs. The sub-hole HLEs can be defined by physically passing through the display panel 100_2 in the thickness direction (the third direction DR3).

The polarization layer 200, the cover layer 300, the back plate 400, and the heat dissipation sheet 500 can correspond to the flat surface shape of the display panel 100_2. Each of the polarization layer 200, the cover layer 300, the back plate 400, and the heat dissipation sheet 500 can include a through hole that physically passes therethrough. The through hole of each of the polarization layer 200, the cover layer 300, the back plate 400, and the heat dissipation sheet 500 can have substantially the same location and size as the sub-hole HLEs of the display panel 100_2 in a plan view, but is not limited thereto.

The blocking member 600 can cover an exposed side surface of each of the display panel 100_2, the polarization layer 200, the cover layer 300, the back plate 400, the heat dissipation sheet 500, and the adhesive layer 700. The blocking member 600 can cover an area adjacent to the sensor 10 among the exposed side surfaces.

The blocking member 600 can cover an inner wall of the sub-hole HLEs of the display panel 100_2. Furthermore, the blocking member 600 can cover an inner wall of the through-hole of each of the polarization layer 200, the cover layer 300, the back plate 400, and the heat dissipation sheet 500.

The blocking member 600 can cover the inner wall of the sub-hole HLEs of the display panel 100_2. Furthermore, the blocking member 600 can come into direct contact with the inner wall of the through-hole of each of the polarization layer 200, the cover layer 300, the back plate 400, and the heat dissipation sheet 500.

The blocking member 600 can be disposed to surround the sensor 10 in a plan view.

Even in this case, since the blocking member 600 is disposed, it is possible to suppress or prevent the light and/or heat emitted from the sensor 10 from entering the display panel 100 and prevent damage to the display panel 100.

Since the display apparatus 1_2 includes the sensor hole HLE and the sensor 10 is disposed to overlap the sensor hole HLE, the bezel area of the display apparatus 1_2 can be reduced, and various designs can be possible as needed. In addition, since the blocking member 600 is disposed to surround the sensor 10 in a plan view, it is possible to suppress or prevent the heat and light emitted from the sensor 10 from penetrating the display panel 100_2 more smoothly.

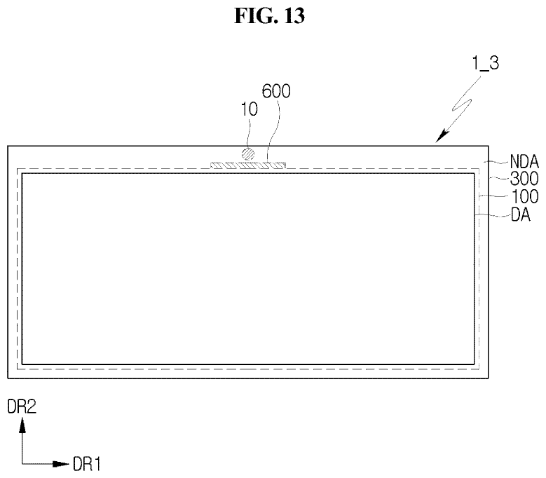

FIG. 13 is a plan view of a display apparatus according to yet another embodiment of the present disclosure.

Referring to FIG. 13, a display apparatus 1_3 according to the present embodiment can include the sensor 10 and the blocking member 600, and the sensor 10 and the blocking member 600 can be disposed in the non-display area NDA.

The display panel 100 may not include the first notch NCP1 (see FIG. 1). The sensor 10 can be disposed in the non-display area NDA disposed at the top in a plan view, and the blocking member 600 can be disposed in the non-display area NDA and disposed around the sensor 10.

Even in this case, since the blocking member 600 is disposed, it is possible to suppress or prevent the light and/or heat emitted from the sensor 10 from entering the display panel 100 and prevent damage to the display panel 100.

Since the display panel 100 does not include the first notch NCP1 (see FIG. 1) and the sensor hole HLE (see FIG. 9), the process can be further simplified.

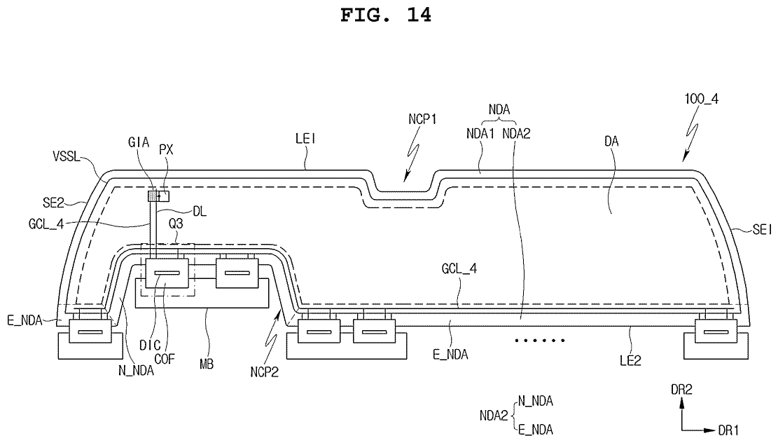

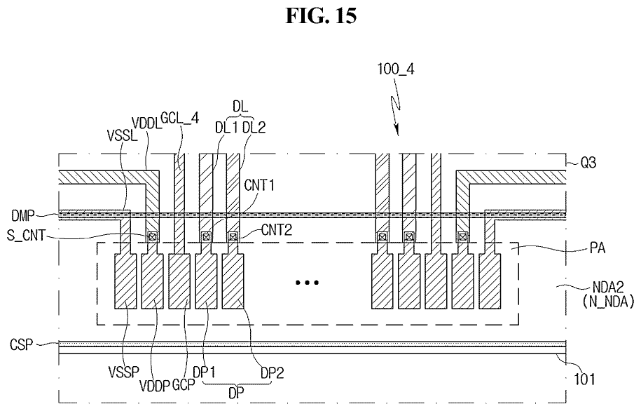

FIG. 14 is a plan view of a display panel according to yet another embodiment of the present disclosure. FIG. 15 is an enlarged view of area Q3 in FIG. 14.

FIG. 15 is a view of area Q3 of a display panel 100_4 according to yet another embodiment of the present disclosure, from which the flexible film COF, the main board MB, and the drive IC DIC are omitted.

Referring to FIGS. 14 and 15, in the display panel 100_4 according to the present embodiment, a separate gate driving unit GIP (see FIG. 3) is not disposed in the non-display area NDA, and the pixel gate driving unit GIA can be disposed in the display area DA.

The pixel gate driving unit GIA can be provided as a plurality of pixel gate drivers, and each pixel gate driving unit GIA can be connected to each of the plurality of pixels PX. The pixel gate driving unit GIA can be disposed around the pixel PX. The pixel gate driving unit GIA can be disposed between adjacent pixels PXs.

For example, the pixel gate driving unit GIA can be disposed between adjacent pixels PXs in the first direction DR1. The pixel PX and the pixel gate driving unit GIA can be alternately repeatedly disposed in the first direction DR1. The pixel PX can be continuously repeatedly disposed in the second direction DR2. The pixel gate driving unit GIA can be continuously repeatedly disposed in the second direction DR2.

The pixel gate driving unit GIA can perform substantially the same role as the gate driving unit GIP (see FIG. 3). The pixel gate driving unit GIA can include at least one transistor.

The pixel gate driving unit GIA can be electrically connected to an adjacent pixel PX.

The pixel gate driving unit GIA can receive a gate control signal from the drive IC DIC through a gate control line GCL_4. The pixel gate driving unit GIA can generate a scan signal and a light-emitting signal (or a light-emitting control signal) based on the gate control signal. Accordingly, the driving of the adjacent pixel PX can be controlled.

Since the pixel gate driving unit GIA is disposed in the display area DA, it is possible to minimize the non-display area NDA or the bezel area, thereby providing improved aesthetic feeling to a user.

The display panel 100_4 can further include the gate control line GCL_4 and the gate control pad GCP.

The gate control line GCL_4 can be disposed in the non-display area NDA and the display area DA. The gate control line GCL_4 can be disposed in the second non-display area NDA2, but is not limited thereto. The gate control line GCL_4 can be disposed in an extension direction of the second non-display area NDA2.

The gate control line GCL_4 can be partially disposed in the second non-display area NDA2 and can extend from the second non-display area NDA2 to the pixel gate driving unit GIA of the display area DA. The gate control line GCL_4 can be electrically connected to the plurality of pixel gate driving units GIAs disposed in the display area DA.

The gate control pad GCP can be disposed in the pad area PA. In the pad area PA, the gate control pad GCP is illustrated as being disposed between the high-potential voltage pad VDDP and the data pad DP, but is not limited thereto, and the arrangement location of the gate control pad GCP can vary according to a design.

The gate control pad GCP can include the same material as the gate control line GCL_4, but is not limited thereto. The gate control pad GCP and the gate control line GCL_4 can be formed integrally, but are not limited thereto.

The gate control pad GCP and the gate control line GCL_4 can be disposed on the fourth insulating layer 106. The gate control pad GCP and the gate control line GCL_4 can be disposed on the same layer as the source electrode 121 (see FIG. 6) and the drain electrode 124 (see FIG. 6) and can include the same material as the source electrode 121 and the drain electrode 124, and the gate control pad GCP, the gate control line GCL, the source electrode 121, and the drain electrode 124 can be formed together using one mask by the same process, but the embodiments of the present disclosure are not limited thereto.

Even in this case, since the blocking member 600 is disposed, it is possible to suppress or prevent the light and/or heat emitted from the sensor 10 (see FIG. 1) from entering the display panel 100 and prevent damage to the display panel 100.

Since the gate driving unit GIP (see FIG. 1) is omitted from the non-display area NDA and the pixel gate driving unit GIA is disposed in the display area DA, the non-display area NDA can be reduced, thereby reducing the bezel area and increasing the display area DA.

A display apparatus according to various embodiments of the present disclosure can be described as follows.

A display apparatus according to embodiments of the present disclosure includes a display panel, a cover layer disposed on the display panel and extending more than the display panel, a sensor disposed outside the display panel and overlapping the cover layer, and a blocking member between the display panel and the sensor in a plan view.

According to various embodiments of the present disclosure, the blocking member can come into direct contact with a side surface of the display panel.

According to various embodiments of the present disclosure, the blocking member can come into direct contact with a lower surface of the cover layer.

According to various embodiments of the present disclosure, the blocking member can include a white-based resin or foam tape.

According to various embodiments of the present disclosure, the display apparatus can further include a back plate below the display panel, and a heat dissipation sheet below the back plate.

According to various embodiments of the present disclosure, the blocking member can come into direct contact with side surfaces of the back plate and side surfaces of the heat dissipation sheet.

According to various embodiments of the present disclosure, the display apparatus can further include a polarization layer between the display panel and the cover layer, and side surfaces of the polarization layer can come into contact with the blocking member.

According to various embodiments of the present disclosure, the blocking member may not overlap the sensor.

According to various embodiments of the present disclosure, a thermal conductivity of the blocking member can range from 0.02 W/mK to 0.025 W/mK.

According to various embodiments of the present disclosure, the display panel can include a notch recessed from at least one edge thereof, the notch can overlap the cover layer, and the sensor can be disposed in the notch.

According to various embodiments of the present disclosure, the display panel can include a sensor hole, and the sensor can overlap the sensor hole.

According to various embodiments of the present disclosure, the display panel can include a display area and a non-display area including a pad area around the display area, and further include a low-potential voltage line and a high-potential voltage line that are electrically connected to the pad area, and in the non-display area below the display area, the high-potential voltage line can be located between the low-potential voltage line and the display area.

According to various embodiments of the present disclosure, the low-potential voltage line can surround the display area.

According to various embodiments of the present disclosure, the non-display area located at a left or right side of the display area can further include a gate driving unit between the low-potential voltage line and the display area.

According to various embodiments of the present disclosure, the display apparatus can further include a pixel gate driving unit located in a display area, a gate control line electrically connecting a pad area to the pixel gate driving unit, in which the gate control line can be located between a low-potential voltage line and the display area.

A display apparatus according to embodiments of the present disclosure includes a display panel, a sensor disposed outside the display panel and disposed below the display panel, and a blocking member that comes into contact with a side surface of the display panel and includes a white-based resin or foam tape, in which the blocking member is disposed between the display panel and the sensor in a plan view.

According to various embodiments of the present disclosure, the display apparatus can further include a back plate below the display panel, and a heat dissipation sheet below the back plate.

According to various embodiments of the present disclosure, the blocking member can come into direct contact with side surfaces of the back plate and side surfaces of the heat dissipation sheet.

According to various embodiments of the present disclosure, the display apparatus can further include a cover layer on the display panel, and a polarization layer between the display panel and the cover layer, in which side surfaces of the polarization layer can come into contact with the blocking member.

According to various embodiments of the present disclosure, the blocking member may not overlap the sensor.

Although the embodiments have been described above with reference to the accompanying drawings, those skilled in the art to which the present disclosure pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

1: display apparatus
10: sensor
100: display panel
200: polarization layer
300: cover layer
400: back plate
500: heat dissipation sheet
600: blocking member
700: adhesive member
NCP: notch
DA: display area
NDA: non-display area
PX: pixel
EA: light-emitting area
NEA: non-light-emitting area
ML: microlens

What is claimed is:

1. A display apparatus comprising:
a display panel;
a cover layer disposed on the display panel and extending beyond the display panel;
a sensor disposed outside the display panel and overlapping the cover layer; and
a blocking member between the display panel and the sensor in a plan view.

2. The display apparatus of claim 1, wherein the blocking member comes into direct contact with a side surface of the display panel.

3. The display apparatus of claim 2, wherein the blocking member comes into direct contact with a lower surface of the cover layer.

4. The display apparatus of claim 1, wherein the blocking member includes a white-based resin or foam tape.

5. The display apparatus of claim 1, further comprising:
a back plate below the display panel; and
a heat dissipation sheet below the back plate.

6. The display apparatus of claim 5, wherein the blocking member comes into direct contact with side surfaces of the back plate and side surfaces of the heat dissipation sheet.

7. The display apparatus of claim 1, further comprising:
a polarization layer between the display panel and the cover layer,
wherein side surfaces of the polarization layer come into contact with the blocking member.

8. The display apparatus of claim 1, wherein the blocking member does not overlap the sensor.

9. The display apparatus of claim 1, wherein a thermal conductivity of the blocking member ranges from 0.02W/mK to 0.025W/mK.

10. The display apparatus of claim 1, wherein the display panel includes a notch that is recessed from at least one edge thereof, and
the notch overlaps the cover layer, and the sensor is disposed in the notch.

11. The display apparatus of claim 1, wherein the display panel includes a sensor hole, and the sensor overlaps the sensor hole.

12. The display apparatus of claim 1, wherein the display panel includes a display area, and a non-display area including a pad area adjacent to the display area,
the display panel further includes a low-potential voltage line and a high-potential voltage line that are electrically connected to the pad area, and
in the non-display area below the display area, the high-potential voltage line is located between the low-potential voltage line and the display area.

13. The display apparatus of claim 12, wherein the low-potential voltage line surrounds the display area.

14. The display apparatus of claim 12, wherein the non-display area located at a first side or second side of the display area further includes a gate driving unit between the low-potential voltage line and the display area, and
the first and second sides of the display area are opposite sides.

15. The display apparatus of claim 12, further comprising:
a pixel gate driving unit located in the display area; and
a gate control line electrically connecting the pad area to the pixel gate driving unit,
wherein the gate control line is located between the low-potential voltage line and the display area.

16. A display apparatus comprising:
a display panel;
a sensor disposed outside the display panel and disposed below the display panel; and
a blocking member in contact with a side surface of the display panel and including a white-based resin or foam tape,
wherein the blocking member is disposed between the display panel and the sensor in a plan view.

17. The display apparatus of claim 16, further comprising:
a back plate below the display panel; and
a heat dissipation sheet below the back plate.

18. The display apparatus of claim 17, wherein the blocking member comes into direct contact with side surfaces of the back plate and side surfaces of the heat dissipation sheet.

19. The display apparatus of claim 16, further comprising:
a cover layer on the display panel; and
a polarization layer between the display panel and the cover layer,
wherein side surfaces of the polarization layer come into contact with the blocking member.

20. The display apparatus of claim 16, wherein the blocking member does not overlap the sensor.
